(19) United States
(12) Patent Application Publication
(10) Pub. No.: US 2024/0372532 A1
(43) Pub. Date: Nov. 7, 2024

(54) RECURSIVE FIR DIGITAL FILTER

(71) Applicant: Safwan AREKAT, Barbar (BH)

(72) Inventor: Safwan AREKAT, Barbar (BH)

(21) Appl. No.: 18/267,378

(22) PCT Filed: Aug. 16, 2022
(86) PCT No.: PCT/IB2022/057643

§ 371 Date: Jun. 14, 2023

(51) Int. Cl. H03H 17/02; H03H 17/04; H03H 17/06

(52) U.S. Cl. CPC H03H 17/0251; H03H 17/04; H03H 17/0671

(57) ABSTRACT

Embodiments of the present disclosure include a method for designing the transfer function of efficient recursive FIR digital filters. The method is based on the cancellation of the poles of the transfer function of a multi-resonator sub-filter by zeros of the transfer function of a muti-stopper sub-filter. A compensator sub-filter can be applied for band shaping, is the method may be used to design low-pass, high-pass and band-pass filters, among other types. The FIR filters can be designed to have either a linear phase or a very nearly linear phase response. IIR filters with a nonlinear phase response can also be designed by the method of this invention. The method may additionally describe a digital circuit for the implementation of the transfer function of the invention.

### 1. TECHNICAL FIELD OF THE INVENTION

The present invention relates to the field of digital signal processing. Specifically, it relates to the design and construction of recursive FIR frequency-selective digital filters.

### 2. BACKGROUND ART

Digital filters play a central role in digital signal processing (DSP) which is one of the foundations of modern electronics technology. The use of linear phase digital filters is significant in applications requiring preserving the integrity of the time domain signal profile by minimizing distortions. Such applications include digital communications, digital audio-visual signal processing, IoT devices, VUI systems, and digital flight control systems. It is known in the art that finite impulse response (FIR) digital filters with a symmetric impulse response exhibit an exact linear phase response and are therefore well suited for such applications. Traditionally, linear phase FIR filters have been realized by using non-recursive techniques where the current output signal of the system is obtained by the processing the current and past inputs. But it has also been shown in the art that linear phase FIR filters can be realized by employing recursive techniques, where the current output is obtained by processing the current and past inputs—along with past outputs in feedback loops. Examples of such recursive FIR designs are provided in several sources (C. Rader, “Digital Filter Design Techniques in the Frequency Domain, Proceedings of the IEEE, Vol. 55, No.2, February 1967, and L. Rabiner, “Techniques for Designing Finite-Duration Impulse-Response Digital Filters”, IEEE Transactions on Communication Technology, Vol Com-19, No.2, April 1971, and by M. Laddomada, “Generalized Comb Decimation Filters for ΣΔ A/D Converters: Analysis and Design, IEEE Transactions on Circuits and Systems-I: Regular Papers, Vol. 54, No.5, May 2007.)

Recursive FIR filters are made possible by the process of zero-pole cancellation in the rational transfer function of the recursive filter. To illustrate this, we first review recursive digital filter basics. Consider the causal time domain system difference-equation of a general digital filter to be written as

$${\sum }_{i = 0}^{N} {a}_{i} y [ n - i ] = {\sum }_{i = 0}^{M} {b}_{i} x [ n - i ]$$

with y[n−i] being the output signal at time instant n−i, x[n−i] is the input signal at time instant n−i, and with n and i being positive integers. bᵢ and aᵢ are real valued coefficients. The output is calculated at regular time intervals called the sampling rate which is taken to be unity in the above expression (sampling frequency fₛ=1 Hz). The output at time instant n is calculated as

$$y [ n ] = {\sum }_{i = 0}^{M} \frac{{b}_{i}}{{a}_{0}} x [ n - i ] - {\sum }_{i = 1}^{N} \frac{{a}_{i}}{{a}_{0}} y [ n - i ] .$$

The present and past inputs sum is called the feedforward term, and the past outputs sum is called the feedback term. To study the resulting frequency response, a discrete z-transform of the difference equation is taken, which becomes

$${\sum }_{i = 0}^{N} {a}_{i} {z}^{- i} \tilde{Y} ( z ) = {\sum }_{i = 0}^{M} {b}_{i} {z}^{- i} \tilde{X} ( z )$$

where z−1=e^{-jω}, with ω=2πf, and f is the signal frequency having a maximum value of

$$\frac{{f}_{s}}{2}$$

(0.5 Hz in the present case) as limited by the Sampling Theorem. The transfer function can be written as the ratio of two polynomials

$$\begin{matrix}\tilde{H} ( z ) = \frac{\tilde{Y} ( z )}{\tilde{X} ( z )} = \frac{{\sum }_{i = 0}^{M} {b}_{i} {z}^{- i}}{1 + {\sum }_{i = 1}^{N} {a}_{i} {z}^{- i}} \\ or \\ \tilde{H} ( z ) = \frac{{b}_{0} + {b}_{1} {z}^{- 1} + {b}_{2} {z}^{- 2} + …}{1 + {a}_{1} {z}^{- 1} + {a}_{2} {z}^{- 2} + …}\end{matrix}$$

with \tilde{H}(z) being a frequency dependent complex function, and a₀ being set to unity without loss in generality. It is customary to define the magnitude |\tilde{H}(z)|=|\tilde{H}(e^{jω})| as the amplitude response, and the argument arg(\tilde{H}(z))=arg(\tilde{H}(e^{jω})) as the phase response. The transfer function can be factored as

$$\tilde{H} ( z ) = \frac{{\prod }_{i = 0}^{M - 1} ( z - {z}_{z i} )}{{∐}_{i = 0}^{N - 1} ( z - {z}_{p i} )} = \frac{( z - {z}_{z 0} ) ( z - {z}_{z 1} ) … ( z - {z}_{z ( M - 1 )} )}{( z - {z}_{p 0} ) ( z - {z}_{p 1} ) … ( z - {z}_{p ( N - 1 )} )}$$

with the numerator roots defining the zeros (z_{zi}) and the denominator roots defining the poles (zₚᵢ) of the transfer function. The zeros make the transfer function evaluate to zero, and poles make the transfer function infinite. For stable filter operation, all poles must be inside, or on the circumference of a circle of unity radius in the z-domain (i.e. |z|≤1). Importantly also, zeros and poles must be either real-valued, or present in complex conjugate pairs to ensure a real-valued filter. The strategy for achieving recursive FIR filters is to select polynomials that result in the complete cancellation of the denominator roots. A subset of the zeros must cancel all the poles of the transfer function. This requires that the order of the numerator (M) be greater than that of the denominator (N). The effective transfer function after the cancellation will have only zeros in it, and thus is characterized by a finite impulse response. Furthermore, it can be arranged that the remaining zeros are either on the unit circle, or alternatively occur in reciprocal complex conjugate pairs to provide a transfer function having a linear phase.

A distinguished example that is well known in the art for a recursive linear phase FIR filter is the Cascaded Integrator-Comb Filter (CIC), developed by Eugene Hogenauer (E. Hogenauer, “An Economical Class of Digital Filters for Decimation and Interpolation”, IEEE Transactions on Acoustics, Speech and Signal Processing, Vol. ASSP-29, pp. 155-162, April 1981). The (CIC) filter is a computationally efficient multiplier-less implementation of narrowband lowpass filters. They are often embedded in hardware implementations of decimation and interpolation in modern communications systems. The filter has a cascade of repeated stages each with a single-pole integrator (accumulator) comprising the feedback term, in series with a feedforward comb filter. We bypass the discussion of the difference in sampling rates between the integrator and the comb sections to concentrate on the relevance of this filter to the present invention. The composite transfer function of each single stage of the CIC filter (assuming a rate change factor of unity) can be simplified to

$$\tilde{H} ( z ) = \frac{1}{M} \frac{1 - {z}^{- M}}{1 - {z}^{- 1}}$$

where M is an integer representing the comb differential delay, and the 1/M term is needed for zero-frequency normalization. Obviously, this constitutes a recursive filter because feedback is involved. However, this is still an FIR filter since the effective impulse response has only zeros resulting from the complete cancellation of the pole. To demonstrate this, the numerator is factored as,

$$\tilde{H} ( z ) = \frac{1}{M} \cdot \frac{{\prod }_{k = 0}^{M - 1} ( {e}^{j \frac{2 π k}{M}} - {z}^{- 1} )}{( 1 - {z}^{- 1} )} = \frac{1}{M} \cdot \frac{{\prod }_{k = 1}^{M - 1} ( {e}^{j \frac{2 π k}{M}} - {z}^{- 1} )}{}$$

resulting in the cancellation of the single pole. It can be shown that the transfer function reduces to

$$\tilde{H} ( z ) = \frac{{\sum }_{k = 0}^{M - 1} {z}^{- k}}{M} = \frac{1 + {z}^{- 1} + {z}^{- 2} + … + {z}^{- ( M - 1 )}}{M}$$

which is simply the transfer function of a running average filter of length M, with M zeros on the unit circle, and having a finite impulse response and a linear phase relation (because of coefficient symmetry). Even though the pole has been effectively cancelled from the transfer function, it is still an integral component for the realization and the operation of the filter implementing the full transfer function. The cancellation in the CIC is a perfect cancellation since the cancelled pole, which lies on the unit circle, has a unity coefficient which is not limited by coefficient quantization.

One objective of the present invention is to provide a method for designing efficient frequency selective linear phase recursive FIR filters.

More familiar to DSP practitioners is the use of recursive techniques for the design and construction of Infinite Impulse Response (IIR) filters. These filters offer low order efficient implementations for obtaining sharp transitions between passbands and stopbands of frequency selective filters. Their low order also provides a fast filter response and a low output signal delay (group delay). However, IIR filters are limited by their non-linear phase relationship. Techniques exist for equalizing this phase distortion by employing all-pass filters, but this comes at the expense of reducing the efficiency advantage. Three classical IIR filter designs are the Butterworth, Chebyshev and Elliptic filter designs. These classical filters take advantage of the bilinear transformation between the continuous s-plane and the discrete z-plane.

Another objective of the present invention is to provide a method for designing efficient nonclassical frequency selective recursive IIR filters.

### 3. INVENTION SUMMARY

A major aspect of this invention is designing an efficient recursive digital filter that is characterized by having a linear phase response and a finite impulse response.

According to a major aspect of the present invention, a filter is proposed which comprises a plurality of sub-filters that interact together to provide a compound filter. One of the sub-filters, designated here as the “Multi-Resonator (M.R.)”, comprises one or more interconnected elementary filters, each having a transfer function with a magnitude response that maximizes indefinitely, or to a finite maximum value, at each frequency in a discrete set of unique frequencies. These maxima result from the poles of the elementary filters of the M.R. sub-filter. Another sub-filter, designated here as the “Multi-Stopper (M.S.)”, comprises one or more interconnected elementary filters, each having a transfer function with a magnitude that minimizes to zero, or to a finite minimum value, at each frequency in a discrete set of unique frequencies. These minima result from the zeros of the elementary filters of the M.S. sub-filter.

The filter system combining a cascaded pair of M.R. and M.S. sub-filters described in is designated in this disclosure as a “Lobe-filter”, having a transfer function that is formed by the product of the transfer functions of the two sub-filters. The M.R. and M.S. sub-filters are selected, as detailed in this summary, to produce a lobe-filter that has either an exact linear phase response at all frequencies, or alternatively, a nearly linear phase response—except near a discrete set of frequencies situated in the stopband of the filter.

A significant aspect of the present invention is that the plurality of sub-filters described above in include a “Compensator” sub-filter used for band shaping, the details of which are given in this description.

FIG. 1 illustrates a block diagram of a compound filter representing a significant aspect of the invention. The first block represents the lobe-filter, which itself comprises two subcomponents being the M.R. and the M.S. sub-filters as described in [0010]. The second block represents the Compensator sub-filter mentioned in [0011]. The input signal to the compound filter is connected to the input of the M.R. sub-filter. The output of the M.R. sub-filter is connected to the input of the M.S. sub-filter. The output signal of the M.S. sub-filter is connected to the input of the Compensator sub-filter. The output of the compound filter is taken from the output of the Compensator. Being connected in series, the ordering of all blocks and subcomponents is interchangeable without affecting the transfer function of the compound filter. In all cases, the input to the filter is connected to the input of the first stage in the series, and the output of the filter is taken from the output of the last stage in the series.

A significant aspect of the invention is that the transfer function of the lobe-filter described in [0010] is configured such that the M.R. sub-filter transfer function has a total number of poles that is less than the total number of zeros of the M.S. sub-filter transfer function.

Another major aspect of the invention is that the lobe-filter is configured such that the angles and the radii of the poles of the M.R. sub-filter transfer function, are matched to the angles and radii of an equal number of zeros of the M.S. sub-filter transfer function. This leads to a pole-zero cancellation upon the product of the two sub-filter transfer functions, resulting in the mutual cancellation of the aforementioned pole induced maxima and zero induced minima features of the individual sub-filter transfer functions, such that these features are eliminated from the magnitude response of the product transfer function of the lobe-filter. Specifically, this cancellation results in an all-zero effective lobe-filter transfer function having a magnitude response of a finite value at all frequencies. The frequencies at which these pole-zero (maxima-minima) cancellations occur are symbolized as fₙ in H_{z}, or ωₙ=2πfₙ in rad., where n is an integer index referencing the cancelled pole-zero pairs.

A significant aspect of the present invention is that one or more of the frequencies fₙ of the cancelled pole-zero pairs, as described in [0014], lie within bounded frequency intervals, such that the lobe-filter transfer function has a pronounced finite maximum value in its magnitude response in these frequency intervals. The magnitude response within each interval forming a lobe-shaped passband that decreases monotonically away from the lobe maximum towards the bounds of each interval. The bounds of each lobe-shape being local minima in the magnitude response of the lobe transfer function. (A note: The filters described in this invention are real-valued filters having real-valued coefficients. This gives transfer functions having magnitude responses that are symmetrical about zero frequency, and as a consequence, a lobe-shaped passband at positive frequencies will have a mirror image at negative frequencies).

An embodiment of the invention is to employ an all-zero linear phase FIR filter as the compensator sub-filter mentioned in [0011] for band shaping of the lobe-shaped passband magnitude response described in [0015]. This FIR compensation will result in the filter of the invention being a recursive linear phase FIR filter.

Another significant embodiment of the invention is to employ an all-pole IIR filter as the compensator sub-filter mentioned in [0011] for band shaping of the lobe-shaped passband magnitude response described in [0015]. This IIR compensation will result in the filter of the invention being a recursive IIR filter.

A significant embodiment of the invention is that the M.S. sub-filter comprise elementary filters that are a single feedforward comb filter, or a plurality of such interconnected feedforward comb filters, each with a transfer function having one of the two forms

$$\begin{matrix}{\tilde{H}}_{c o mb - , l} ( z ) = 1 - {β}_{l}^{{M}_{l}} \cdot {z}^{- {M}_{l}} \\ or \\ {\tilde{H}}_{c o mb + , l} ( z ) = 1 + {β}_{l}^{{M}_{l}} \cdot {z}^{- {M}_{l}}\end{matrix}$$

where l is an integer index referencing unique comb filters in the M.S. sub-filter, βₗ is the uniform radius of all the zeros of the l^{th} comb filter which is a real number in the range 0<βₗ≤1, and Mₗ is a positive integer representing the differential delay for each comb filter. H_{comb-,l}(z) has Mₗ zeros located at

$${z}_{zl , k} = {β}_{l} {e}^{\pm j \frac{2 π k}{M}} ,$$

with magnitude response minima occurring at

$${f}_{l k} = \pm \frac{k}{{M}_{l}} .$$

k is a positive integer k=0, 1, . . . kₘₐₓ limited by the condition fₗₖ_{ₘₐₓ}≤0.5 Hz. H_{comb+,l}(z) has Mₗ zeros located at

$${z}_{zl , k} = {β}_{l} {e}^{\pm j \frac{2 π ( 2 k + 1 )}{2 {M}_{l}}} ,$$

with magnitude response minima occurring at

$${f}_{l k} = \pm \frac{( 2 k + 1 )}{2 {M}_{l}} .$$

k is a positive integer k=0, 1, . . . limited by the condition fₗₖ_{ₘₐₓ}≤0.5 Hz.

Another significant embodiment of the invention is that the M.R. sub-filter comprise elementary filters that are a single complex conjugate two-pole-section (resonator), or a plurality of interconnected complex conjugate two-pole-sections, each having a transfer function of the form

$${\tilde{H}}_{r e son , n} ( z ) = \frac{1}{1 - 2 {r}_{n} cos ( {θ}_{n} ) {z}^{- 1} + {{r}_{n}}^{2} {z}^{- 2}} = \frac{1}{( 1 - {r}_{n} {e}^{j {θ}_{n}} {z}^{- 1} ) ( 1 - {r}_{n} {e}^{- j {θ}_{n}} {z}^{- 1} )}$$

where n is an integer referencing unique two-pole sections, rₙ is the pole radius having a positive value in the range 0<rₙ≤1 as required for stability, and θₙ is the pole angle (−θₙ for the conjugate pole). This gives the two poles of each resonator to be z_{pn±}=rₙe^{±jθ}^{ₙ}. The pole angles θₙ (in radians) are also equal to the radial frequencies (ωₙ) at which the magnitude response maxima occur. In general, the values of rₙ and θₙ are different for each resonator, and the manner in which their values are set is described in this summary. If the poles are set to lie on the real axis at either θₙ=0 or θₙ=π, the expression for \tilde{H}_{Res,n}(z) will have a degenerate pair of real poles at the same radius. In this case, it is necessary to reduce the order of the corresponding transfer function to first order having only one pole, by eliminating the other pole. \tilde{H}_{reson,n}(z) becomes a single order accumulator section of one of the forms

$$\begin{matrix}{\tilde{H}}_{r e s o n , n} ( z ) = \frac{1}{1 - {r}_{n} {z}^{- 1}} for a pole angle of {θ}_{n} = 0 , \\ or \\ {\tilde{H}}_{r e s o n , n} ( z ) = \frac{1}{1 + {r}_{n} {z}^{- 1}} for a pole angle of {θ}_{n} = π .\end{matrix}$$

FIG. 2 displays a block diagram illustrating a significant embodiment of the lobe-filter defined in [0010] whose operation is described in [0012] to [0015]. The first block represents the M.R. sub-filter comprising a single two-pole resonator section as described in [0019], or a cascade assembly of N such resonators. The second block represents the M.S. sub-filter, which in this embodiment, comprises a single comb filter with differential delay M as described in [0018], with M being larger than the number of resonator stages N, and having a transfer function given by either \tilde{H}_{comb-,l}(z) or \tilde{H}_{comb+,l}(z).

A significant embodiment of this invention is based on a lobe-filter having an M.S. sub-filter that is made of a single a comb filter, one as described in [0018] and illustrated in [0020], and having a transfer function of the form \tilde{H}_{M.S.}(z)=\tilde{H}_{comb+}(z)=1+β^{M}z^{-M}. The M.R. sub-filter in this embodiment, has a number N two-pole resonators, each as described in [0019], all being connected in series as illustrated in [0020]. This M.R. sub-filter has a transfer function of the form

$${\tilde{H}}_{M . R .} ( z ) = {\prod }_{n = 1}^{N} \frac{1}{1 - 2 {r}_{n} cos ( {θ}_{n} ) {z}^{- 1} + {{r}_{n}}^{2} {z}^{- 2}}$$

and the overall lobe-filter transfer function is given by

$${\tilde{H}}_{l o b e} ( z ) = {\tilde{H}}_{M . S .} ( z ) \cdot {\tilde{H}}_{M . R .} ( z ) = ( 1 + {β}^{M} {z}^{- M} ) \cdot {\prod }_{n = 1}^{N} \frac{1}{1 - 2 {r}_{n} cos ( {θ}_{n} ) {z}^{- 1} + {r}_{n}^{2} {z}^{- 2}}$$

The frequencies of the M minima of the comb magnitude response are located at the frequencies

$${f}_{k} = \pm \frac{( 2 k + 1 )}{2 M} ,$$

with k being a positive integer k=0, 1, . . . limited by the condition fₖ≤0.5. The lobe-shaped passband magnitude response described in [0015] is created by selecting for cancellation a single zero, or groups of neighboring zeros of the comb filter, by the M.R. sub-filter resonator poles. The cancellation of all the poles of the transfer function is effected by the following two steps: a) the radii rₙ of all poles are set equal to the radius of the zeros of the comb filter, i.e., rₙ=β. b) the frequency of the maxima of each resonator is matched to the frequency of the corresponding minima of the comb filter, i.e., the angles of the poles and zeros that are to be cancelled are matched: θₙ=ωₙ=2πfₖ. It is important to emphasize that the full expression of \tilde{H}_{lobe}(z) —prior to pole-zero cancellation—that is to be implemented for the advantages of this invention to be realized.

This specific simulation demonstrates the lobe-filter described in [0021]. The comb parameters are set: M=10 and β=0.925. The magnitude response, being |\tilde{H}_{comb+}(e^{jω})|, is plotted in FIG. 3a. The response has 10 minima situated at

$${f}_{k} = \pm \frac{( 2 k + 1 )}{20} ,$$

with k=0, 1, 2, 3, 4. The M.R. sub-filter in this demonstration has parameters N=2, meaning a pair of two-pole resonators,

$${\tilde{H}}_{M . R .} ( z ) = \frac{1}{1 - 2 β cos ( {θ}_{1} ) {z}^{- 1} + {β}^{2} {z}^{- 2}} \cdot \frac{1}{1 - 2 β cos ( {θ}_{2} ) {z}^{- 1} + {β}^{2} {z}^{- 2}}$$

The pole angle of the first resonator is chosen to be θ₁=ω₁=2πf₀, where f₀=0.05 Hz is the frequency of the first zero of the comb-filter having index k=0. The pole angle of the second resonator is chosen to be θ₂=ω₂=2πf₁, where f₁=0.15 Hz is the frequency of the second zero of the comb-filter with index k=1. The magnitude response of the M.R. sub-filter, being |\tilde{H}_{M.R.}(e^{jω})|, is displayed in FIG. 3a, which shows that the maxima of the M.R. sub-filter (resonators) coincide in frequency to an equal number of minima of the M.S. Sub-filter (comb). The overall transfer function of the lobe-filter becomes

$${\tilde{H}}_{l o b e} ( z ) = \frac{1 + {β}^{M} {z}^{- M}}{( 1 - 2 β c o s ( {θ}_{1} ) {z}^{- 1} + {β}^{2} {z}^{- 2} ) \cdot ( 1 - 2 βcos ( {θ}_{2} ) {z}^{- 1} + {β}^{2} {z}^{- 2} )}$$

and its magnitude response, being magnitudes |\tilde{H}_{lobe}(e^{jω})|=|\tilde{H}_{comb}(e^{jω})·\tilde{H}_{M.R.}(e^{jω})|, is displayed in FIG. 3b. The lobe-shaped passband magnitude described in [0015] is apparent in the graph, it is this feature that enables, through compensation, the obtaining of frequency selective filters. FIG. 3c is the magnitude response of the lobe-filter calculated in dB as is standard in the art. The effective transfer function for \tilde{H}_{lobe}(z) has only zeros in it and is thus characterized by having a finite impulse response. This is verified directly by calculating the Inverse Discrete Time Fourier Transform of \tilde{H}_{lobe}(z), giving the impulse response shown in FIG. 3e. The impulse response is only nearly symmetrical (perfect symmetry is regained for the limiting case β=1). The group delay, shown in FIG. 3d, is nearly constant within most of the passband lobe, giving a nearly linear phase response. A preferred embodiment of this invention involves setting the parameter β=1, resulting in a symmetrical impulse response and an exact linear phase relationship, as described in the preferred embodiment of this disclosure.

The lobe-filter exemplified in [0022] is suitable as a low-pass filter. The needed low-frequency flat-passband can be created by a suitable compensator sub-filter. The stopband attenuation of the lobe-filter increases with the number of pole-zero pairs that are cancelled. Different simulations are performed using both \tilde{H}_{comb+}(z) and \tilde{H}_{comb} (z) as well as enough resonators to supply the needed poles for cancellation. FIG. 4 displays the dependence of the stopband attenuation on the comb parameter M and on the number of cancelled pole-zero pairs. The stopband attenuation level is defined as the height (in dB) of the side lobe of the magnitude response. An important observation in FIG. 4 is that the attenuation increases for increasing number of cancelled pairs. Also, the attenuation is mostly independent of the M delay parameter.

To portray the versatility of the invention, another example of a similar embodiment as in [0022] is provided. But here, the parameters are changed to M=20 and β=0.95. There are twenty zeros in this case. Three pole-zero matched pairs are selected for cancellations (six counting conjugates), and thus requiring three two-pole resonators (N=3). The pole angle of the first resonator is set to be θ₁=ω₁=2πf₃, where f₃=0.175 Hz is the frequency of the fourth zero of the comb-filter having index k=3. The pole angle of the second resonator is set to be θ₂=ω₂=2πf₄, where f₄=0.225 Hz is the frequency of the fifth zero of the comb-filter having index k=4. The pole angle of the third resonator is set to be θ₃=ω₃=2πf₅, where f₅=0.275 Hz is the frequency of the sixth zero of the comb-filter having index k=5. FIG. 5a displays the resulting magnitude response of the lobe-filter. A passband lobe is apparent at intermediate frequencies. In this case, the magnitude response is suitable for adaptation into a band-pass filter. Additionally, just as in the previous example, the magnitude response is symmetric around zero frequency, which is required for a real-valued filter. The group delay is shown in FIG. 5b, where it is nearly constant within most of the passband lobe.

The embodiment involving the FIR compensator sub-filter introduced in [0016] is further detailed here. This sub-filter is connected in series with the lobe-filter as described in [0012] with the purpose of flattening the pass bands. For efficiency purposes, the filter should have the lowest possible order. Furthermore, it should have a symmetrical impulse response to give a linear phase. The compensator transfer function, designated as \tilde{H}_{compens}(z), will have only zeros in it. The zeros need to be located within the passband to actuate passband formation. As is known in the art, this is possible if \tilde{H}_{compens}(z) includes complex zeros root pairs of the form

$$complex zeroes : ( 1 - 2 {ρ}_{1} cos ( ϕ ) {z}^{- 1} + {ρ}_{1}^{2} {z}^{- 2} ) ( 1 - 2 {ρ}_{2} cos ( ϕ ) {z}^{- 1} + {ρ}_{2}^{2} {z}^{- 2} )$$

This term gives four zeros (counting two complex conjugate pairs), with ρ₁ and ρ₂ being the zero radii, at a common angle ϕ. This configuration produces linear phase if the zeros are a reciprocal pair subject to the constraint ρ₂=ρ₁⁻¹=ρ⁻¹. With this constraint, one zero will be inside the unit circle, while the other will be outside the unit circle. Positioning the compensation zeros on the unit circle is avoided as this will make the transfer function evaluate to zero in the passband—which is clearly undesirable. For a low-pass filter, it is suitable to include zeros on the real axis (ϕ=0). In this case the roots can be reduced to only two real axis reciprocal zeros, given by

$${\tilde{H}}_{c o m p e n s} ( z ) = ( 1 - ρ {z}^{- 1} ) ( 1 - {ρ}^{- 1} {z}^{- 1} ) .$$

In general, a suitable transfer function for the FIR linear phase compensator can be constructed as the product of one or more complex zeros that come as reciprocal linear phase pairs as follows

$${\tilde{H}}_{c o m p e n s} ( z ) = {\prod }_{i = 1}^{Q} ( 1 - 2 {ρ}_{i} cos ( {ϕ}_{i} ) {z}^{- 1} + {ρ}_{i}^{2} {z}^{- 2} ) ( 1 - 2 {ρ}_{i}^{- 1} cos ( {ϕ}_{i} ) {z}^{- 1} + {ρ}_{i}^{- 2} {z}^{- 2} ) .$$

Here, i is an index referencing a unique complex reciprocal zero-pair, and Q is the number of reciprocal pairs used in the design. An efficient design necessitates minimizing the number of zeros in \tilde{H}_{compens}(z), and hence the number of reciprocal pairs. For a given value of Q, the number of filter coefficients is 4(Q−1)+2 if real axis zeros are included, and 4Q if only complex reciprocal pairs are present. A person skilled in the art, with the aid of computer numerical simulations, can obtain a set of suitable parameters (ρ₀, ρ₁, ϕᵢ and Q) through a process of iteration, which will result in obtaining the required filter specifications. An example of this procedure is given in the preferred embodiment.

The embodiment involving the IIR compensator sub-filter introduced in [0017] is further detailed here. This sub-filter is connected in series with the lobe-filter as described in [0012] with the purpose of flattening the pass bands. An efficient design is to employ a feedback comb filter having the transfer function of the form

$${\tilde{H}}_{c o m p e n s} ( z ) = \frac{1}{1 + γ \cdot {Z}^{- L}}$$

with γ being a real constant in the range 0<γ<1 as necessary for stability and effectiveness, and L is the differential delay of the comb filter. A person skilled in the art, with the aid of computer numerical simulation, can obtain suitable values for parameters L and γ, through a process of iteration, that will result in obtaining the required filter specifications. An example of this procedure is given later in the description.

The manner in which the present invention is advantageous for linear phase filters is described here. Standard non-recursive FIR filter methods for designing narrowband linear phase filters, such as the Windowing or the Parks-McClellan methods, generally require a large filter order to achieve narrowband specifications. When these methods are implemented as imbedded circuit designs for DSP applications, the large number of filter coefficients necessitates a similarly large number of digital multiplier circuits for the realization of filters having sharp narrowband transitions. The savings in the hardware afforded by the present invention for achieving similar specifications will be demonstrated in the preferred embodiment of this invention disclosure. As applied in the embodiments, the invention can be based on efficient zero-rich comb filters. The zeros can be made to be either uniformly or non-uniformly spaced within the entire frequency range, with the intervals between them also being controllable. It requires the cancellation of one to a few pole-zero pairs to obtain reasonable stopband attenuation. The invention allows for the construction of efficient low pass, high-pass and band pass filters. In addition of low pass differentiators. The invention also allows the construction of IIR filters that are more efficient than classical IIR filters such as Elliptic IIR filters.

### 4. BRIEF DESCRIPTION OF THE DRAWINGS

So that the manner in which the above recited features of the present disclosure can be understood in detail, a more particular description of the disclosure, may have been referred by embodiments, some of which are illustrated in the appended drawings. It is to be noted, however, that the appended drawings illustrate only typical embodiments of this disclosure and are therefore not to be considered limiting of its scope, for the disclosure may admit other equally effective embodiments.

These and other features, benefits, and advantages of the present disclosure will become clearer by reference to the following figures, wherein:

FIG. 1 illustrates a block diagram of an embodiment of the invention comprising M.R., M.S. and Compensator sub-filters;

FIG. 2 shows an embodiment of the invention detailing the lobe-filter as comprising of N cascaded two-pole resonators in series with a feedforward comb filter;

FIG. 3a plots the linear scale magnitude response of the M.S. sub-filter and the M.R. sub-filter, being |\tilde{H}_{comb+}(e^{jω})| and |\tilde{H}_{M.R.}(e^{jω})| respectively, as exemplified in [0022]; FIG. 3b demonstrates the comb-filter linear scale magnitude response |\tilde{H}_{lobe}(e^{jω})| as the product |\tilde{H}_{com}(e^{jω})·\tilde{H}_{M.R.}(e^{jω})|;

FIGS. 3c, d, and e display the normalized dB magnitude response, the group delay and the impulse response of the lobe-filter transfer function \tilde{H}_{lobe}(z) exemplified in [0022], respectively;

FIG. 4 shows a graph of the dependence of the stopband attenuation of the low-pass lobe-filter on the comb filter differential delay M, and the number of cancelled pole-zero pairs N;

FIGS. 5a, b and c display the normalized dB magnitude response, the group delay and the impulse response of the lobe-filter transfer function \tilde{H}_{lobe}(z) exemplified in [0024],respectively;

FIG. 6 illustrates a circuit for realizing the preferred embodiment filter as a cascade connection of sub-filter components;

FIG. 7a and FIG. 7b show the normalized dB scale magnitude responses of the preferred embodiment for a narrowband low-pass filter and that of a similar Parks-McClellan filter;

FIG. 8a and FIG. 8b show the normalized dB scale magnitude responses of the preferred embodiment for a low-pass filter and that of a similar Parks-McClellan filter;

FIG. 9 shows the normalized dB scale magnitude responses of the preferred embodiment for a wideband low-pass filter and that of a similar Parks-McClellan filter;

FIG. 10a and FIG. 10b show the normalized dB scale magnitude responses of the preferred embodiment for a band-pass filter and that of a similar Parks-McClellan filter;

FIG. 11a and FIG. 11b show the normalized dB scale magnitude responses of the preferred embodiment for a high-pass filter and that of a similar Parks-McClellan filter;

FIG. 12 shows a linear scale magnitude response of the preferred embodiment for a low pass differentiator (LPD);

FIG. 13a displays the normalized dB scale magnitude response of a low-pass filter embodiment with a varying beta parameter, while FIG. 13b displays the corresponding frequency response;

FIG. 14 illustrates a circuit for realizing a filter as a cascade connection of sub-filter components;

FIG. 15a show the normalized dB scale magnitude responses of an embodiment for a low-pass filter using comb-filter feedback compensation and that of a similar elliptic IIR filter, while FIG. 15b shows the corresponding group delay.

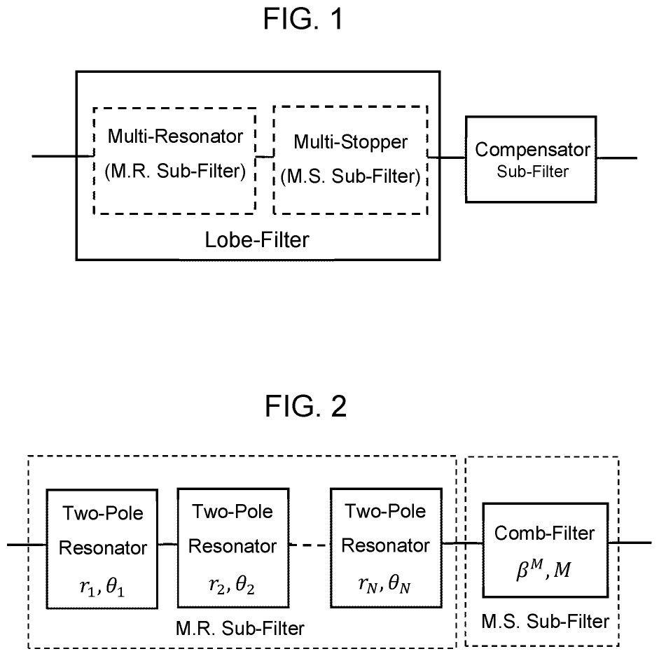

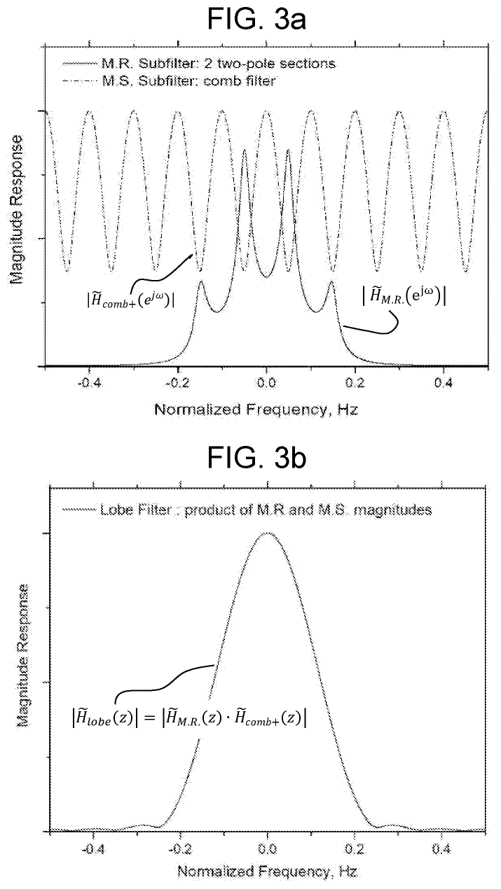

### 5. DESCRIPTION OF THE PREFERRED EMBODIMENT

Detailed embodiments of the preferred mode are described herein; however, it is to be understood that such embodiments are exemplary of the present disclosure, which may be embodied in various alternative forms. Specific process details disclosed herein are not to be interpreted as limiting, but merely as a representative basis for teaching one skilled in the art to variously employ the present disclosure in any appropriate process.

The terms used herein are for the purpose of describing exemplary preferred embodiments only and are not intended to be limiting. As used herein, the singular forms “a,” “an,” and “the” are intended to include the plural forms as well, unless the context clearly indicates otherwise. It will be further understood that the described methods and mathematical forms do not preclude the presence or addition of one or more steps, terms or operations other than a mentioned step, term or operation.

The embodiments of the present disclosure will now be described more fully hereinafter with reference to the accompanying drawings, which form a part hereof, and which show, by way of illustration, specific example embodiments.

### 5.1 The Preferred Embodiment: a Linear Phase Lobe-Filter

The preferred embodiment is a design method for a frequency selective digital filter, and a related filter device, based on a lobe-filter and a compensation sub-filter as described in the invention summary. Specifically, the lobe-filter has an all-zero M.S. sub-filter in the form of a comb filter with transfer function \tilde{H}_{M.S} [symbol] =\tilde{H}_{comb+}(z)=1+z^{-M}, and an all-pole M.R. sub-filter in the form of serially connected two-pole resonator sections, having the transfer function

$${\tilde{H}}_{M . R .} ( z ) = {\prod }_{n = 1}^{N} \frac{1}{1 - 2 cos ( {θ}_{n} ) {z}^{- 1} + {z}^{- 2}}$$

with all the zeros of the M.S. sub-filter and all the poles of the M.R. sub-filter lying on the unit circle (i.e., rₙ=β=1). The lobe-filter transfer function becomes

$${\tilde{H}}_{l o b e} ( z ) = {\tilde{H}}_{M . S} ( z ) \cdot {\tilde{H}}_{M . R .} ( z ) = ( 1 + {z}^{- M} ) \cdot {\prod }_{n = 1}^{N} \frac{1}{1 - 2 cos ( {θ}_{n} ) {z}^{- 1} + {z}^{- 2}}$$

A crucial step is to arrange for the cancellation of all the poles in the lobe-filter transfer function by suitable assignment of the parameters as described and exemplified in the invention summary. A lobe-filter with the prescribed specifications will have an effective transfer function with a recursive symmetric, finite impulse response and an exact linear phase relationship. The lobe-filter is guaranteed to be stable because the two poles of the symmetric denominator polynomial 1−2 cos(θₙ)z⁻¹+z⁻² have unity radius and are therefore pinned to the unit circle for all values of coefficient 2 cos(θₙ). This constraint survives the process of coefficient quantization since the symmetry of the second order polynomial is not affected by quantization.

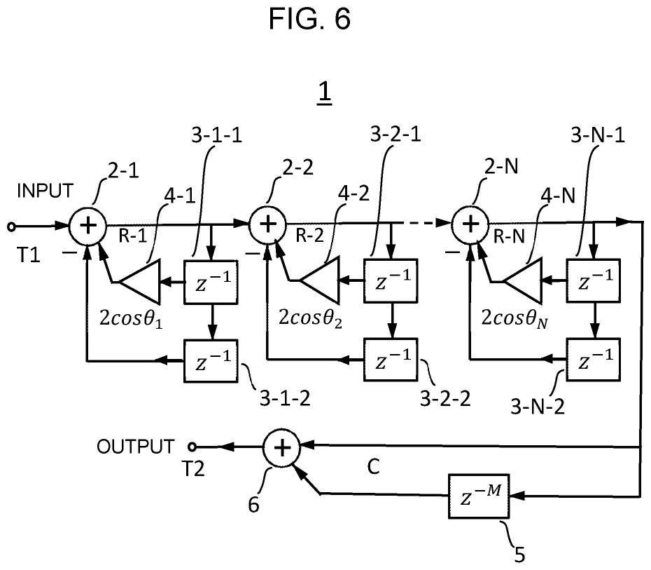

The transfer function \tilde{H}_{lobe}(z) of the preferred embodiment in [0049] can be realized by the cascade circuit configuration of FIG. 6. In circuit (1), the M.R. sub-filter circuit has N two-pole resonators (R-1 to R-N) connected in cascade, with a single feedforward comb filter (C) connected in series with the resonators. There are N resonator adders (2-1 to 2-N), with one adder for each resonator. There are 2N resonator delay units (3-1-1(2) to 3-N-1(2)), with two delay units for each resonator. There are N resonator multipliers (4-1 to 4-N), with one multiplier for each resonator. The output of the resonator adders (2-1 to 2-(N-1)) are connected to the adders of the next resonators. The outputs of the resonator adders are also fed back directly to the adders of the same resonators through delay units (3-1-2 to 3-N-2). The outputs of the resonator adders are also fed back to the adders of the same resonators through delay units (3-1-1 to 3-N-1) and multipliers (4-1 to 4-N). The input signal to the filter enters at T1 which is fed into the adder of the first resonator (2-1). The output of the last resonator (R-N) is fed into the input of the z^{-M} delay unit (5), and to the input of adder (6) of the comb filter. The output of the filter is taken at terminal T2 at adder (6) output.

It is well known in the art that transfer functions, similar to the preferred embodiment, can be implemented in a variety of circuits other than that described in [0050], such as the direct, parallel or the coupled form circuits. The preferred embodiment can also be implemented by programming a Field Programable Field Arrays (FPGA), as well as serial processors such as a personal computer (PC).

The preferred embodiment makes it possible to choose the pass-band type of the filter by selecting the frequencies of the comb filter zeros to be cancelled by suitable pole placements. For a low-pass filter, N neighbouring low-frequency zeros are selected, starting with the lowest frequency zero of the comb filter (k=0). For a high-pass filter, N neighbouring high-frequency zeros are selected, ending with the highest possible zero frequency of the comb filter used (k=kₘₐₓ). For a band pass filter, N neighbouring intermediate zero frequencies are selected to coincide with the required passband.

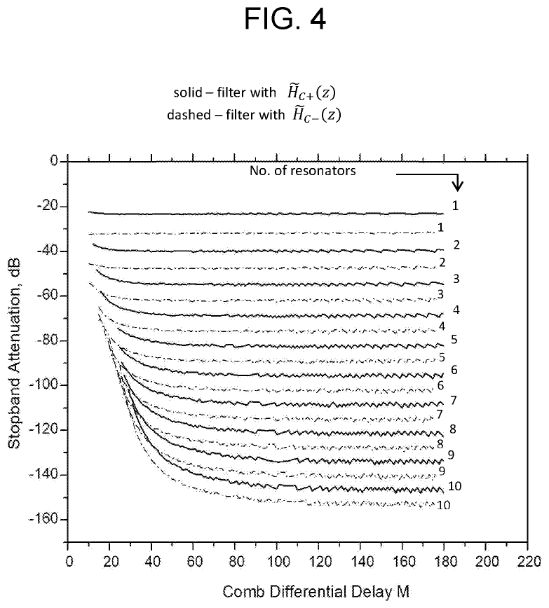

The preferred embodiment enables a wide range of stopband attenuation specifications to be met by including the needed number N of cancelling pole-zero pairs, being equal to the number of two-pole resonators in the M.R. sub-filter. The larger the number N of cancelling pairs, the deeper the stop band attenuation, as demonstrated in [0023] and in FIG. 4.

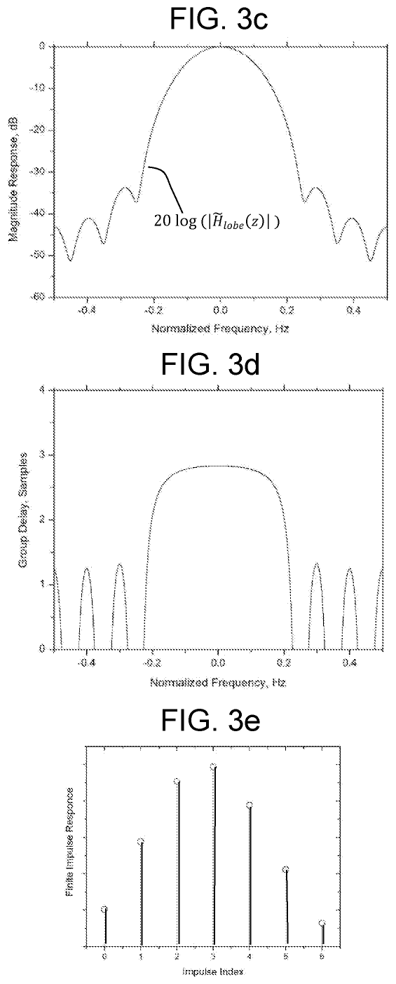

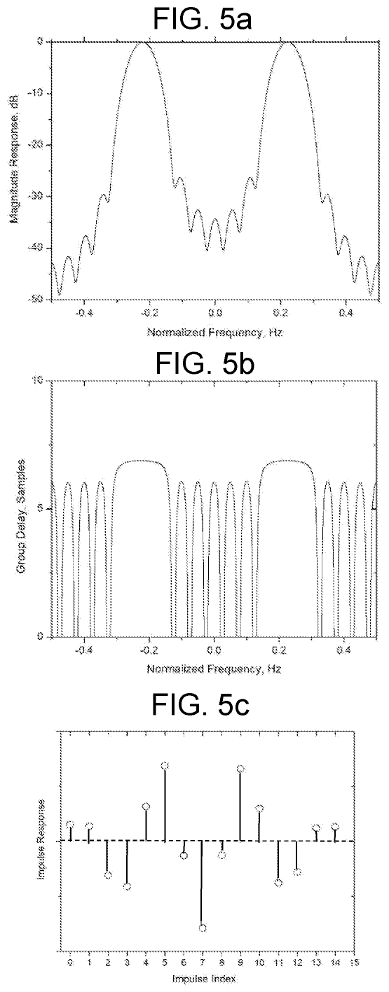

The preferred embodiment enables the control of the passband lobe width (Δ) of the lobe-filter by the dual adjustment of both the comb filter differential delay M and the number of cancelled pole-zero pairs N, where Δ is inversely proportional to M and directly proportional to N. This way, different values of the stopband attenuation are possible for the same passband lobe width. The width Δ also depends on whether there is an overlap between the positive and negative frequency passband lobes of the magnitude response, as in the case for the low-pass filter in FIG. 3, or if they are separated by un-cancelled zeros, as is the case for the band-pass filter in FIG. 5. For a low-pass or a high-pass filter

$$Δ = \frac{2 N + 1}{M} ,$$

while for a band-pass filter

$$Δ = \frac{N + 1}{M} .$$

The preferred embodiment includes a compensator FIR sub-filter where band shaping compensation is achieved by multiplying \tilde{H}_{lobe}(z) by a symmetric non-recursive FIR transfer functions \tilde{H}_{compens}(z) as described in [0025]. The overall filter transfer function becomes \tilde{H}_{filter}(z)=\tilde{H}_{lobe}(z)·\tilde{H}_{compens}(z). The transfer function \tilde{H}_{compens}(z) may include real axis zeros and/or a plurality of complex reciprocal zero pairs, neither of which lie on the unit circle, as necessary to achieve the required compensation. The total number of reciprocal zero pairs is assigned the symbol Q, as described in [0025]. To be effective, the zeros are positioned within the passbands of the filter. The symmetric FIR filter coefficients of the compensator FIR sub-filter can then be obtained as the coefficients of the expanded expression of \tilde{H}_{compens}(z).

### 5.2 Exemplifications of the Preferred Embodiment

The preferred embodiment of [0049] is exemplified next in paragraphs [0057] to [0061]. These represent simulations of the magnitude and phase response of the filter transfer function \tilde{H}_{filter}(z)=\tilde{H}_{lobe}(z)·\tilde{H}_{compens}(z), for low-pass, bandpass and high-pass filters. In each simulation, the performance of the invention filter is compared to a filter having the same characteristics, designed by the conventional Parks-McClellan equiripple method (P.M.), which is well-known in the art.

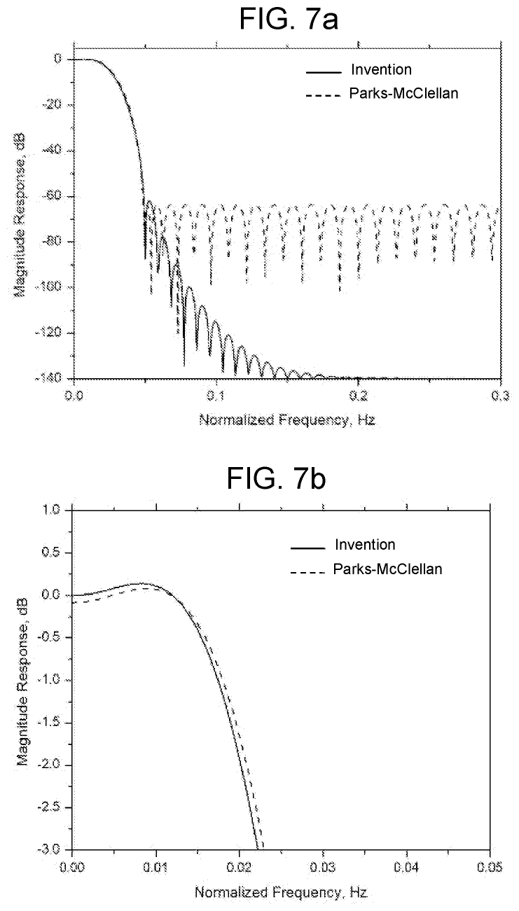

FIG. 7a,b display the dB magnitude response of a linear phase narrow-band low-pass filter designed by the preferred embodiment of this invention. The figure also shows the magnitude response of a filter designed by the P.M. method. The filter characteristics and a comparison is given in the table herein

| Characteristics | Parks-McClellan | Invention |
|---|---|---|
| passband upper frequency fₚ (Hz) | 0.013 | 0.013 |
| stopband lower frequency fₛ(Hz) | 0.049 | 0.049 |
| stopband attenuation (dB) | −63.5 | −61.9 |
| passband pk-pk ripple (dB) | 0.25 | 0.25 |
| group delay (Samples) | 37.5 | 51.0 |
| no. of non-integer coefficients | 75 | 7 |

The parameters used in the design are M=110 and N=5, with k=0, 1, 2, 3, 4 being the indices of the cancelled pole-zero pairs. The compensator has only a pair of positive real axis zeros (Q=1) with parameter ρ=0.89, giving an \tilde{H}_{compens}(z) with two non-integer coefficients. In addition, the filter has five resonators requiring one non-integer coefficient each. The number of coefficients required for the invention filter is 4(Q−1)+2+N, which amount to 7 in this case (2 for compensator and 5 for resonators), while 75 coefficients are required by the P.M. filter. The invention clearly offers a distinct advantage in requiring less circuit multipliers to realize the transfer function coefficients, at the cost of a higher group delay. Importantly as well, the invention deep stopband attenuation is orders of magnitude better that the P.M. filter.

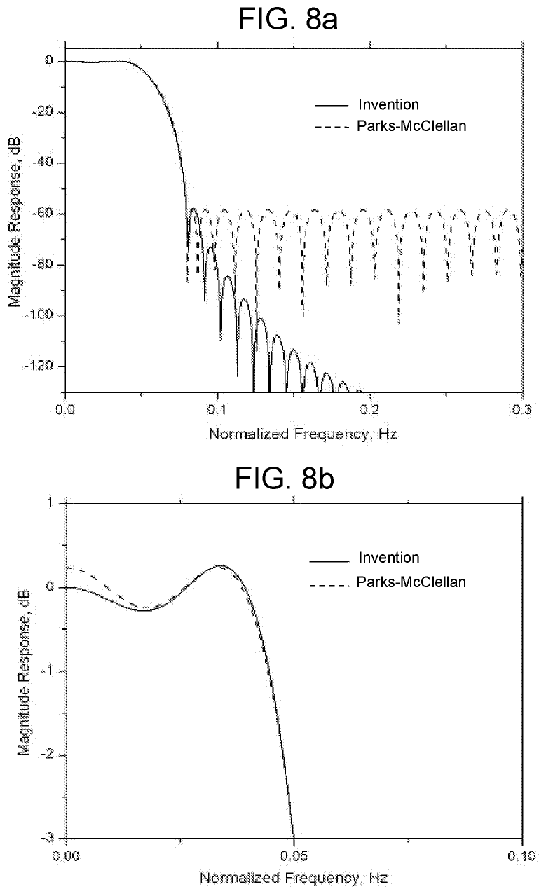

FIG. 8a,b display the dB magnitude response of another linear phase narrow-band low-pass filter designed by the preferred embodiment of this invention. The figure also shows the magnitude response of a filter designed by the P.M. method. The filter characteristics and a comparison is given in the table herein

| Characteristics | Parks-McClellan | Invention |
|---|---|---|
| passband upper frequency fₚ (Hz) | 0.040 | 0.040 |
| stopband lower frequency fₛ(Hz) | 0.080 | 0.079 |
| stopband attenuation (dB) | −58.2 | −57.9 |
| passband pk-pk ripple (dB) | 0.48 | 0.50 |
| group delay (Samples) | 31.5 | 42.5 |
| no. of non-integer coefficients | 63 | 13 |

The parameters used in the design are M=93 and N=7, with k=0, 1, 2, 3, 4, 5, 6 being the indices of the cancelled pole-zero pairs. The compensator has Q=2, with a pair of positive real axis zeros with parameter ρ=0.797 and a pair of complex conjugate zeros with parameters ρ₁=0.856 at angle ϕ₁=0.1382 rad., giving an \tilde{H}_{compens}(z) with six non-integer coefficients. In addition, the filter has seven resonators requiring one non-integer coefficient each. The table shows the number of coefficients required for the invention filter to be 13(4(Q−1)+2=6 for compensator and N=7 for resonators), while 63 coefficients are required by the P.M. filter. The invention clearly offers a distinct advantage in requiring less circuit multipliers to realize the transfer function coefficients, at the cost of higher group delay. Importantly as well, the invention deep stopband attenuation is orders of magnitude better that the P.M. filter.

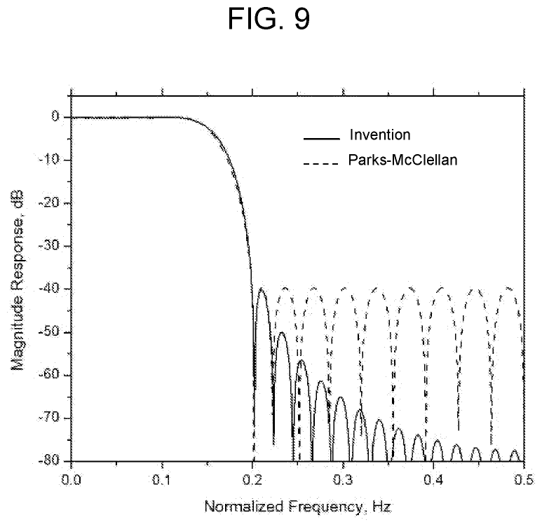

FIG. 9 displays the dB magnitude response of another linear phase narrow-band low-pass filter designed by the preferred embodiment of this invention. The figure also shows the magnitude response of a filter designed by the P.M. method. The filter characteristics and a comparison is given in the table herein

| Characteristics | Parks-McClellan | Invention |
|---|---|---|
| passband upper frequency fₚ (Hz) | 0.121 | 0.122 |
| stopband lower frequency fₛ(Hz) | 0.199 | 0.198 |
| stopband attenuation (dB) | −40.5 | −40.2 |
| passband pk-pk ripple (dB) | 0.24 | 0.24 |
| group delay (Samples) | 13.5 | 21.5 |
| no. of non-integer coefficients | 27 | 23 |

The parameters used in the design are M=47 and N=9, with k=0, 1, 2, 3, 4, 5, 6, 7, 8being the indices of the cancelled pole-zero pairs. The compensator has Q=4 with a pair of positive real axis zeros with parameter ρ=0.698, and three pairs of complex conjugate zeros with parameters ρ₁=ρ₂=ρ₃=0.71 at angles ϕ₁=0.2828 rad., ϕ₂=0.5656 rad. and ϕ₃=0.8484 rad., giving an \tilde{H}_{compens}(z) with fourteen non-integer coefficients. In addition, the filter has nine resonators requiring one non-integer coefficient each. The table shows the number of coefficients required for the invention filter to be 23(4(Q−1)+2=14 for compensator and N=9 for resonators), while 27 coefficients are required by the P.M. filter. The invention offers some advantage in requiring less circuit multipliers to realize the transfer function coefficients, at the cost of higher group delay.

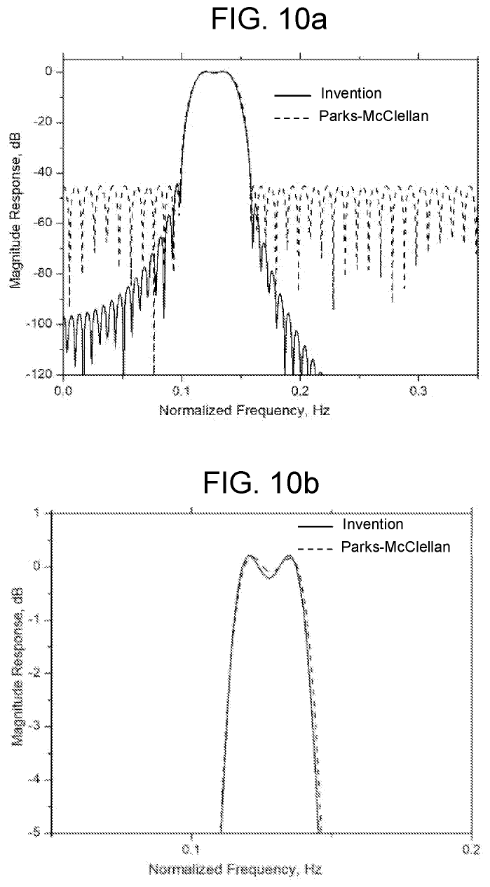

FIG. 10a,b display the dB magnitude response of linear phase narrowband band-pass filter designed by the preferred embodiment of this invention. The figure also shows the magnitude response of a filter designed by the P.M. method. The filter characteristics and a comparison is given in the table herein

| Characteristics | Parks-McClellan | Invention |
|---|---|---|
| upper bandwidth (Hz) | 0.021 | 0.021 |
| lower bandwidth (Hz) | 0.059 | 0.060 |
| passband centre (Hz) | 0.128 | 0.128 |
| stopband attenuation (dB) | −45 | −45 |
| passband pk-pk ripple (dB) | 0.40 | 0.41 |
| group delay (Samples) | 50.0 | 67.5 |
| no. of non-integer coefficients | 100 | 12 |

The parameters used in the design are M=147 and N=8, with k=16, 17, 18, 19, 20, 21, 22, 23 being the indices of the cancelled pole-zero pairs. The compensator has Q=1 with only a single pair of complex conjugate zeros with parameters ρ₁=0.93 at angle ϕ₁=0.8017 rad., giving an \tilde{H}_{compens}(z) with six non-integer coefficients. In addition, the filter has eight resonators requiring one non-integer coefficient each. The table shows the number of coefficients required for the invention filter to be 12(4Q=4 for compensator and N=8 for resonators), while 100 coefficients are required by the P.M. filter. The invention clearly offers a distinct advantage in requiring less circuit multipliers to realize the transfer function coefficients, at the cost of higher group delay. Importantly as well, the invention deep stopband attenuation is orders of magnitude better that the P.M. filter.

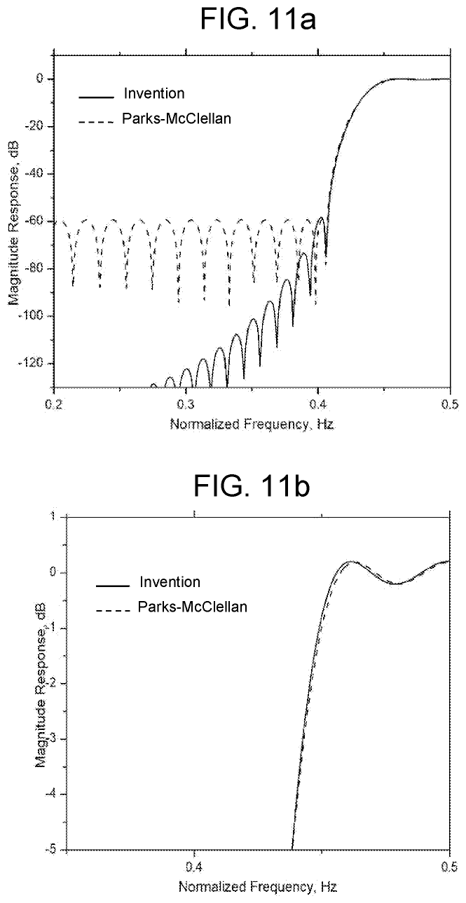

FIG. 11a,b display the dB magnitude response of a linear phase narrow-band high-pass filter designed by the preferred embodiment of this invention. The figure also shows the magnitude response of a filter designed by the P.M. method. The filter characteristics and a comparison is given in the table herein

| Characteristics | Parks-McClellan | Invention |
|---|---|---|
| passband lower frequency fₚ (Hz) | 0.46 | 0.45 |
| stopband upper frequency fₛ(Hz) | 0.41 | 0.40 |
| stopband attenuation (dB) | −59.3 | −59.0 |
| passband pk-pk ripple (dB) | 0.40 | 0.40 |
| group delay (Samples) | 25.5 | 36.0 |
| no. of non-integer coefficients | 51 | 11 |

The parameters used in the design are M=80 and N=7, with k=33, 34, 35, 36, 37, 38, 39 being the indices of the cancelled pole-zero pairs. The compensator has Q=2 with a pair of negative real axis zeros with parameter ρ=0.75 and a single pair of complex conjugate zeros with parameters ρ₁=0.835 at angle ϕ₁=2.9845 rad., giving an \tilde{H}_{compens}(z) with six non-integer coefficients. In addition, the filter has seven resonators requiring one non-integer coefficient each. The table shows the number of coefficients required for the invention filter to be 13(4(Q−1)+2=6 for compensator and N=7 for resonators), while 51 coefficients are required by the P.M. filter. The invention clearly offers a distinct advantage in requiring less circuit multipliers to realize the transfer function coefficients, at the cost of higher group delay. Importantly as well, the invention deep stopband attenuation is orders of magnitude better that the P.M. filter.

### 6. Other Embodiments

An important embodiment of this invention allows for an alternative design of the recursive FIR filter's types encountered in the preferred embodiment of the previous section. Herein, the constraint that all roots of the M.R. and M.S. sub-filter transfer functions must lie on the unit circle is removed. The zeros of the comb transfer function and poles of the resonator transfer functions migrate inside the unit circle, in a way that still supports pole-zero cancellation. This situation has already been covered in the general description for the lobe-filter in paragraphs [0018] to [0023], of which the preferred embodiment of [0049] is only a special case. The transfer function for the lobe-filter in this embodiment is \tilde{H}_{lobe}(z)

$${\tilde{H}}_{l o b e} ( z ) = {\tilde{H}}_{M . S .} ( z ) \cdot {\tilde{H}}_{M . R .} ( z ) = ( 1 + {β}^{M} {z}^{- M} ) \cdot {\prod }_{n = 1}^{N} \frac{1}{1 - 2 βcos ( {θ}_{n} ) {z}^{- 1} + {β}^{2} {z}^{- 2}}$$

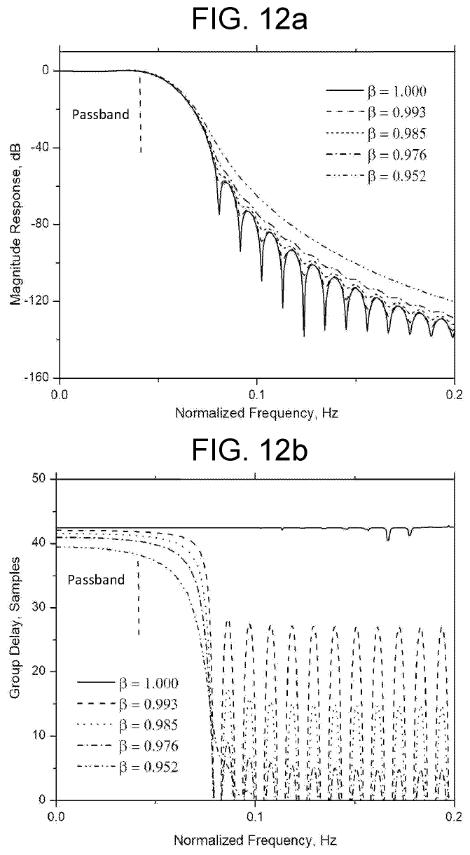

To exemplify this embodiment, a re-simulation is provided of the example for the low-pass filter presented in above. All parameters are kept unchanged—except for β—being the roots of unified radius. (The compensation sub-filter is not changed). FIG. 12a gives the normalized magnitude response for several reduced β values, where a “smoothing effect” in the magnitude response is observed. FIG. 12b shows the group delay dependency on β, where the phase response is observed to be reduced, and to depart slightly from linearity. However, the nonlinearity is relatively minute in the passband, such that the response The impulse response of this embodiment is verified can still be effectively designated as a linear phase filter, to have a finite duration (FIR), as confirmed by calculating the Inverse Discrete Time Fourier Transform, and is nearly symmetrical, with perfect symmetry regained for the case β=1. The embodiment pit resented in this paragraph may be useful to reduce the group delay, but importantly, it allows for alternative implementations such as that known in the art as the “coupled form”, for which different coefficient quantization conditions are valid. However, this embodiment is not as efficient as preferred embodiment case having β=1, since more coefficient multipliers are required. Specifically, N+1 additional non-integer coefficients are needed in the transfer function of this embodiment. For example, the filter of [0058], which was re-simulated here, requires a total of 21 filter coefficients (13 original and 8 additional), which is still much lower than the 63 coefficients required for the P.M. equiripple filter.

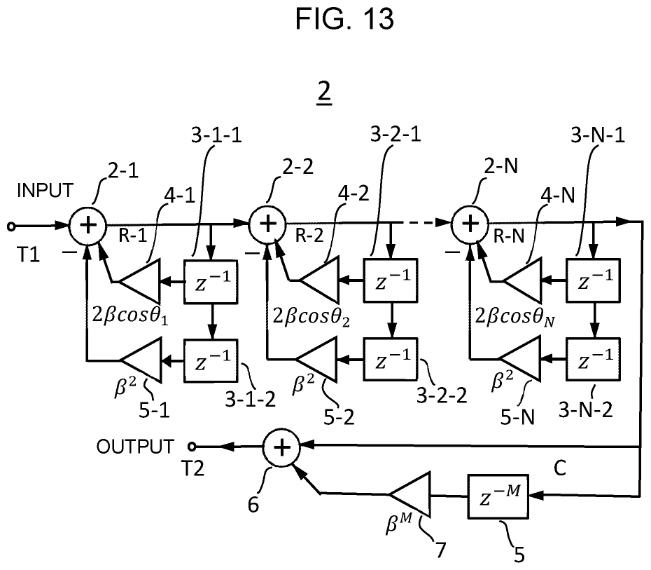

One way of realizing the transfer function \tilde{H}_{lobe}(z) in the embodiment of [0062] is using circuit 2 of FIG. 13. It is the same as circuit (1) described in [0050] of the preferred embodiment, except for the addition of N multipliers (5-1 to 5-N) following the delay units (3-1-2 to 3-N-2). The comb section has an additional multiplier (7) after the z^{-M} delay unit (5). It is to be noted that other circuits are known in the art for realizing the embodiment such as the direct, parallel or the coupled forms. The embodiment can also be implemented by programming a Field Programable Field Arrays (FPGA) as well as serial processors such as a general-purpose personal computer (PC).

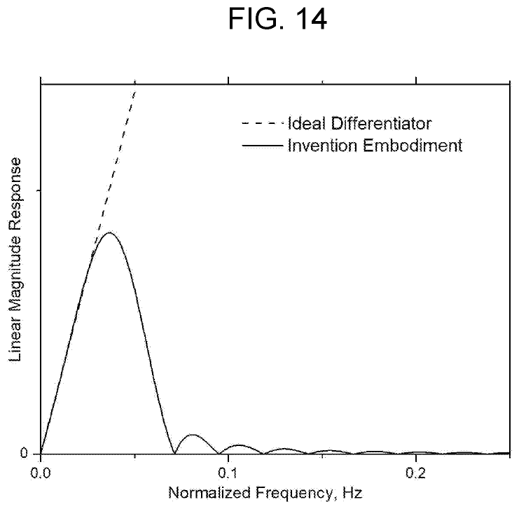

FIG. 14 displays the linear scale passband magnitude response of an embodiment of a Low Pass Differentiator Filter (LPD). It is constructed in the same way as in the preferred embodiment, except that the M.S. sub-filter has the alternate transfer function \tilde{H}_{M.S} [symbol] =\tilde{H}_{comb-}(z)=1−z^{-M}. The M.R. sub-filter and compensator have the same form as in the preferred embodiment. In this simulation, the comb filter differential delay is M=42, and the first zero (k=0) at zero frequency is left uncancelled, with the next two zeros at k=1 and k=2 being cancelled by the poles of two resonators (N=2). The compensator sub-filter has Q=1, with a pair of reciprocal positive real axis zeros with ρ=0.82. Different LPD characteristics may be obtained by changing M, N and the compensation sub-filter. FIG. 14 shows a linear frequency dependence at low frequencies as required for a differentiator. This continues up to a certain cut-off frequency beyond which the response is attenuated.

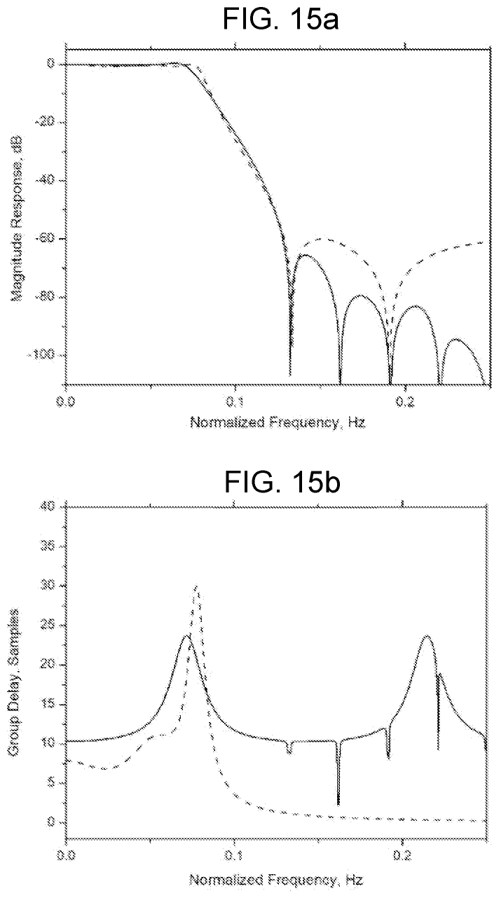

Another embodiment utilizing the lobe-filter of the preferred embodiment [0049] or the alternative form described in [0062 ] is the design of an IIR filter. Here the compensator sub-filter has the form of the feedback comb filter described in [0026]. FIG. 15a displays the normalized dB magnitude response of the IIR embodiment of the invention together with an order 5 elliptic IIR filter, of similar characteristics, which is well-known to one skilled in the art. FIG. 15b displays the corresponding group delay of the two filters. The invention filter has parameters M=34, L=7, N=4, β=1 and γ=0.605. The total number of coefficients needed for the invention filter is 5 (one for the feedback comb filter and 4 for the resonators of the lobe-filter), while 13 are required for the elliptic filter. A clear advantage is also provided by the invention in the IIR filter case.

Limitations: Traditionally, the reliance on pole-zero cancellation methods in systems design has been viewed to be unreliable. This attitude held especially true for analog systems, where the tolerance in the properties of physical system components could not, in general, be minimized to low enough levels. However, in digital systems, pole-zero cancellation are routinely used in CIC filters, among others. Just like the CIC, the preferred embodiment of the present invention, being the recursive linear phase lobe-filter, has all its zeros and poles residing on the unit circle. This makes coefficient quantization more reliable because of the symmetry constraint placed on the coefficients. For example, only the coefficient 2 cos(θ) need to be quantized in each two-pole resonator section, with the pole remaining pinned to the unit circle, and thus guaranteeing stable operation. However, to effectively carry out pole-zero cancellation, the pole angle that is defined by 2 cos(θ) must be matched closely enough by a corresponding zero angle defined by the comb filter section, satisfying the equation

$$cos ( θ ) = cos ( \frac{2 π ( 2 k + 1 )}{2 M} ) .$$

The term on the right is of mathematical origin having infinite precision. Therefore, satisfying the equation relies on the accuracy of quantizing cos(θ). Simulations show that the quantization of cos(θ) must generally be accurate to the fifth decimal place for the filter performance not to be degraded. Therefore, in general, the quantized coefficients of the filters of this invention must have a word length longer than 16-bits. A conservative choice is to use a word length of 24-bit. This requirement can be met by many of contemporary embedded DSP components and computer systems. All computer numerical simulations in this invention description were made on a 32-bit PC system (a virtual 32-bit system running on a 64-bit host system).

Digital filters are prone to overflow distortions. The usual precautions that are known in the art should be applied to minimize such distortions in the implementation of the filters in this invention. The preferred embodiment of the invention is thought to be free of limit cycle instabilities affecting certain IIR filters, the reason being the impulse response in the preferred embodiment has a finite duration (FIR).

An embodiment of this invention allows for designing a decimation filter in a manner like the CIC filter discussed in [0004]. Here, the M.R. sub-filter (two-pole sections) is operated at a high sampling rate, whereas the M.S. sub-filter (comb section) is operated at a low sampling rate. This procedure can be applied to many of the filter embodiments within this description.

1. A method for designing the transfer function of a recursive finite impulse response digital filter, the method comprising the steps of:
a) selecting a first transfer function comprising a pole or a plurality of poles, and selecting a second transfer function comprising a plurality of zeros, each pole of the first transfer function having a radius and angle that are matched numerically to the radius and angle of one of the zeros of the second transfer function, whereby arranging a one-to-one pairing between the matched poles and zeros of the two transfer functions, the total number of zeros of the second transfer function being more than the number of poles of the first transfer function, thereby one or more zeros of the second transfer function remaining unpaired;
b) multiplying the first transfer function by the second transfer function to obtain a product transfer function comprising the poles and zeros of the first and second transfer functions, thereby effecting the cancellation of the matched pole-zero pairs of the product transfer function, the cancellation resulting in an all-zero effective transfer function characterized by having a finite duration impulse response, the magnitude response of the effective transfer function forming passbands in frequency ranges containing a cancelled pole-zero pair or a grouping of cancelled pole-zero pairs of the product transfer function, the magnitude response of the effective transfer function forming stopbands in frequency ranges containing an uncancelled zero or a plurality of uncancelled zeros of the effective transfer function;
c) An alternative to steps a) and b) is obtaining the same product transfer function of step b) by any mathematical combination of transfer functions, whereby the first and second transfer functions of step a) can be derived from a factored form of the product transfer function;
d) implementing the first transfer function as the transfer function of a first sub-filter and implementing the second transfer function as the transfer function of a second sub-filter, wherein the cascade connection of the two sub-filters constitutes the recursive finite impulse response filter of the invention;
e) an alternative to step d) is implementing the product transfer function directly as the transfer function of the recursive finite impulse response filter of the invention.

2. The method as claimed in claim 1, wherein the first transfer function comprises the transfer function of a two-pole IIR resonator filter or a plurality of cascaded two-pole IIR resonator filters, and the second transfer function comprises the transfer function of a feedforward comb filter or a plurality of cascaded feedforward comb filters.

3. The method as claimed in claim 2, wherein the first transfer function of claim 2 is further multiplied by the transfer function of a single-pole accumulator filter or a plurality of cascaded single-pole accumulator filters.

4. A digital filter circuit that implements the transfer functions of the method of claim 2, the transfer functions being in the form of a product transfer function or the form of factored first and second sub-filter transfer functions, the circuit having any structural form known in the art that is used for realizing recursive filters.

5. A set of code or a computer program of the transfer functions of claim 2 written in any syntax or computer language, the code or program running on any platform such as a PC, FPGA or any other device.

6. The method as claimed in claim 2 wherein the product transfer function is further multiplied by an all-zero transfer function of a linear phase FIR compensator filter, the compensator transfer function comprising a reciprocal pair of zeros or a plurality of reciprocal pairs of zeros.

7. The method as claimed in claim 2 wherein the product transfer function is further multiplied by an all-pole transfer function of an IIR compensator filter, the compensator transfer function being that of a feedback comb filter.

8. A digital filter circuit that implements the transfer functions of the methods of claim 3, the transfer functions being in the form of a product transfer function or the form of factored first and second sub-filter transfer functions, the circuit having any structural form known in the art that is used for realizing recursive filters.

9. A set of code or a computer program of the transfer functions of claim 3 written in any syntax or computer language, the code or program running on any platform such as a PC, FPGA or any other device.

10. The method as claimed in claim 3 wherein the product transfer function is further multiplied by an all-zero transfer function of a linear phase FIR compensator filter, the compensator transfer function comprising a reciprocal pair of zeros or a plurality of reciprocal pairs of zeros.

11. The method as claimed in claim 3 wherein the product transfer function is further multiplied by an all-pole transfer function of an IIR compensator filter, the compensator transfer function being that of a feedback comb filter.
